(19) United States
(12) Patent Application Publication
(10) Pub. No.: US 2026/0114042 A1
(43) Pub. Date: Apr. 23, 2026

(54) CHANNEL STRAIN ENGINEERING FOR SEMICONDUCTOR DEVICES

(71) Applicant: Taiwan Semiconductor Manufacturing Company, Ltd., Hsinchu (TW)

(72) Inventors: Zhi-Chang Lin, Hsinchu County (TW); Ying-Chun Shen, Hsinchu (TW); Szu-Hua Chen, Tainan City (TW); Yu-Hsien Chiang, Hsinchu (TW); Ku-Feng Yang, Hsinchu County (TW); Szuya LIAO, Hsinchu (TW)

(21) Appl. No.: 19/334,057

(22) Filed: Sep. 19, 2025

Related U.S. Application Data
(60) Provisional application No. 63/708,839, filed on Oct. 18, 2024.

(51) Int. Cl. H10D 84/85; H10D 30/69; H10D 84/01

(52) U.S. Cl. CPC H10D 84/854; H10D 84/0167; H10D 84/017; H10D 84/0188; H10D 84/851; H10D 30/797

(57) ABSTRACT

A semiconductor structure according to the present disclosure includes an undoped semiconductor feature in a substrate, a first bottom nanostructure and a second bottom nanostructure over the substrate, a bottom epitaxial feature over the undoped semiconductor feature and between the first bottom nanostructure and the second bottom nanostructure, a first isolation layer over the first bottom nanostructure, a second isolation layer over the second nanostructure, a bottom contact etch stop layer (CESL) over the bottom epitaxial feature, a first top nanostructure over the first isolation layer, a second top nanostructure over the second isolation layer, a top epitaxial feature over the bottom CESL and extending between the first top nanostructure and the second top nanostructure, and a top CESL over the top epitaxial feature. A composition of the bottom CESL is different from a composition of the top CESL.

### PRIORITY DATA

This application claims priority to U.S. Provisional Patent Application No. 63/708,839, filed on Oct. 18, 2024, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method 100 for forming a semiconductor device, according to one or more aspects of the present disclosure.

FIGS. 2-13 illustrate fragmentary cross-sectional views of a precursor structure undergoing various fabrication processes in the method of FIG. 1, according to one or more aspects of the present disclosure.

FIG. 14 illustrates a flow chart of a method 300 for forming a semiconductor device, according to one or more aspects of the present disclosure.

FIGS. 15-28 illustrate fragmentary cross-sectional views of a precursor undergoing various fabrication processes in the method of FIG. 14, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be referred to as a complementary field effect transistor (CFET). The multi-gate devices in a CFET may be FinFETs or GAA transistors. Performance of a CFET may be improved if carrier mobilities in channels of the CFET increase. As described above, the bottom multi-gate device and the top multi-gate device in a CFET may be of different conductivity types. A channel of an n-type device may be subject to tensile stress to improve electron mobility and a channel of a p-type device may be subject to compressive stress to improve hole mobility.

The present disclosure provides methods of fabricating semiconductor devices with improved channel carrier mobilities. In one embodiment, a bottom contact etch stop layer (CESL) is formed over a bottom source/drain feature of a CFET structure to exert a compressive stress on the bottom channels to improve the hole mobility in the bottom channels. After formation of a bottom interlayer dielectric (ILD) layer over the bottom CESL and a top source/drain feature, a top CESL is formed over the top source/drain feature to exert a tensile stress on the top channels to improve the electron mobility in the top channels. In still another embodiment, a bottom source/drain feature is formed in a way to have a bottom recess. The bottom CESL is deposited not only over the bottom source/drain feature but also over the bottom recess to fill the same. After formation of a bottom interlayer dielectric (ILD) layer over the bottom CESL and a top source/drain feature, a top source/drain is formed in way to have a top recess. The top CESL is deposited not only over the top source/drain feature but also over the top recess to fill the same. The bottom recess allows the bottom CESL to better exert compressive stress on the bottom channels and the top recess allows the top CESL to better exert tensile stress on the top channels.

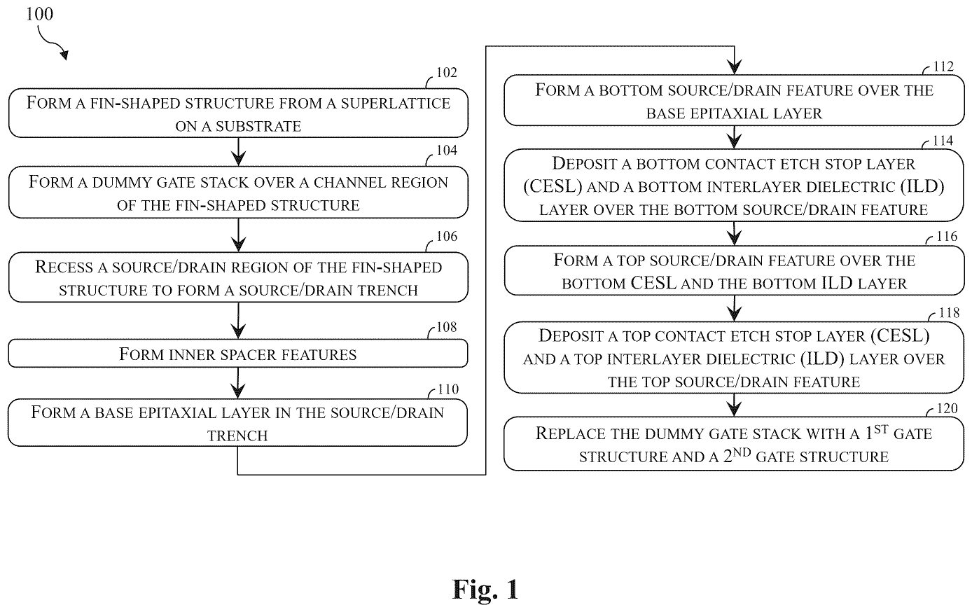

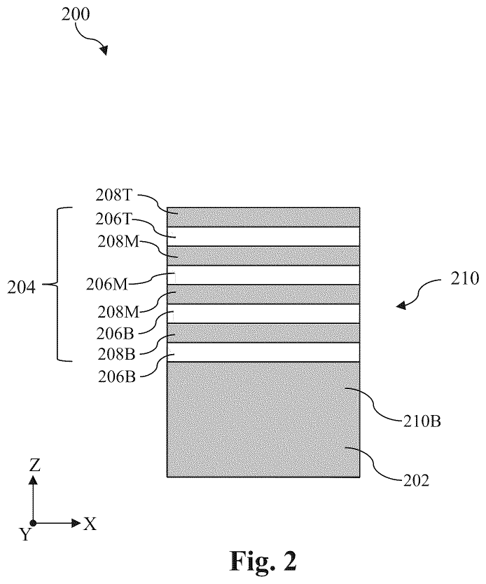

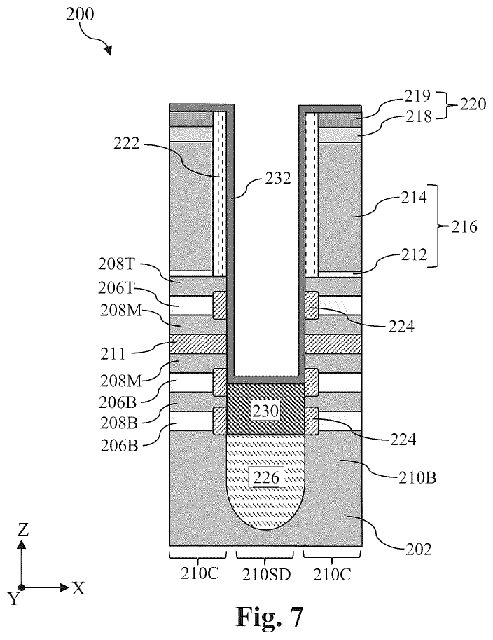

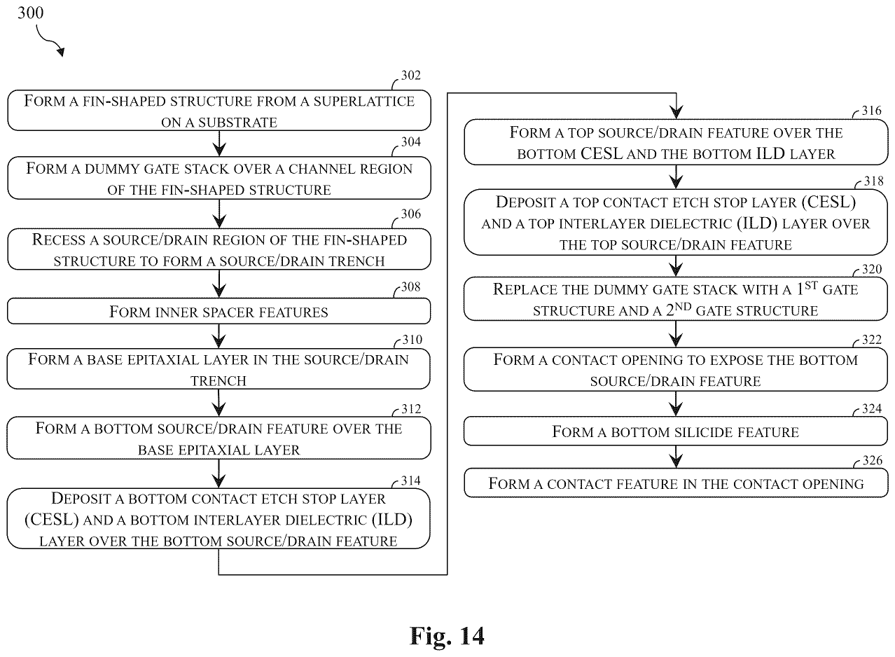

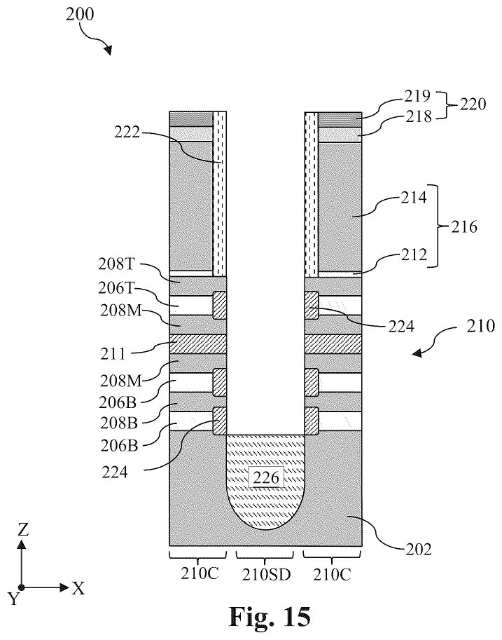

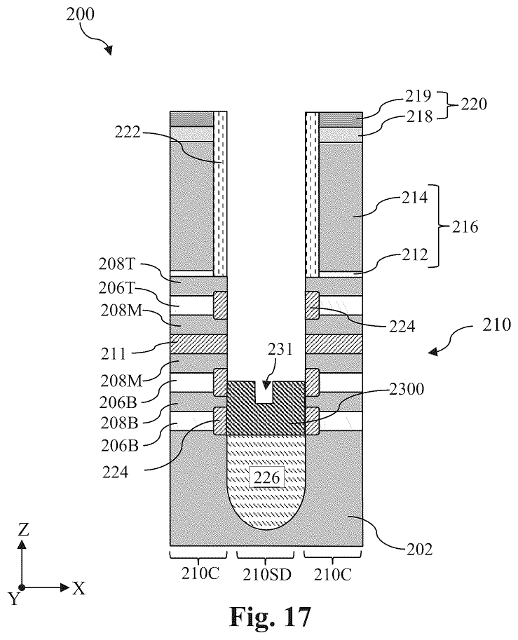

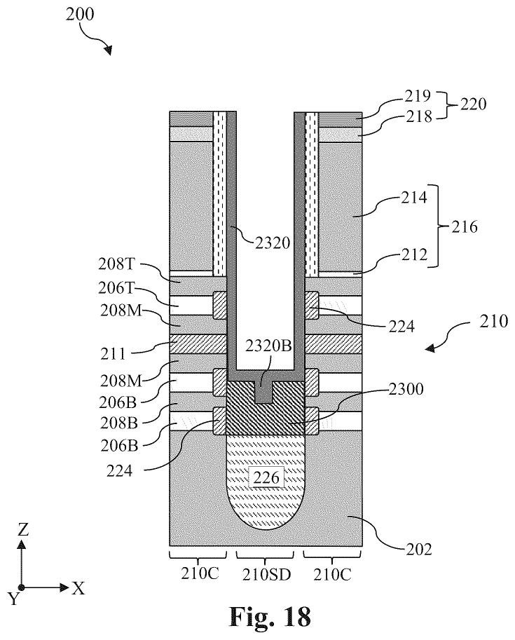

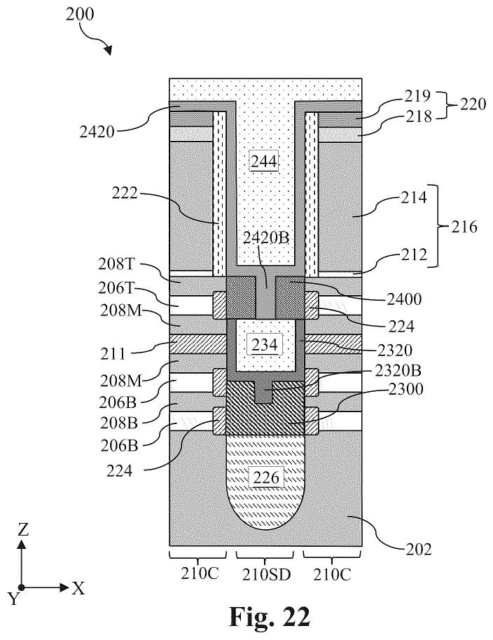

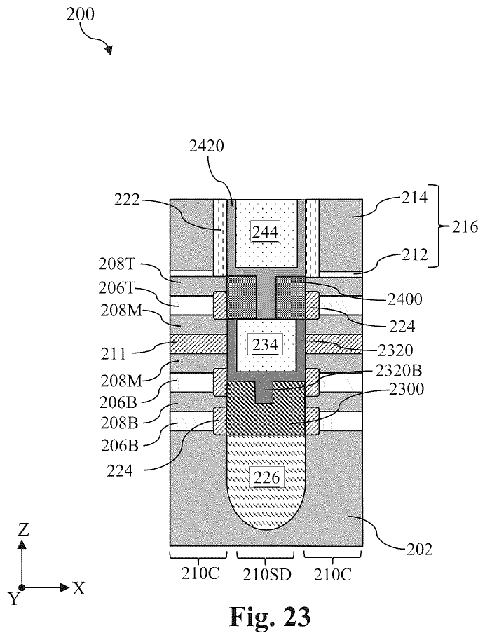

The various aspects of the present disclosure will now be described in more detail with reference to the figures. In that regard, FIGS. 1 and 14 are flowcharts illustrating method 100 and method 300 for forming a semiconductor device according to various aspects of the present disclosure. Methods 100 and 300 are merely examples and are not intended to limit the present disclosure to what is explicitly illustrated in methods 100 and 300. Additional steps may be provided before, during and after methods 100 and 300, and some steps described can be replaced, eliminated, or moved around for additional embodiments of the method. Not all steps are described herein in detail for reasons of simplicity. Method 100 is described below in conjunction with FIGS. 2-13, which are fragmentary cross-sectional views of a precursor structure 200 at different stages of fabrication according to embodiments of method 100. Method 300 is described below in conjunction with FIGS. 15-28, which are fragmentary cross-sectional views of a precursor structure 200 at different stages of fabrication according to embodiments of method 300. Because the precursor structure 200 will be fabricated into a semiconductor device 200 upon conclusion of the fabrication processes, the precursor structure 200 may be referred to as the semiconductor device 200 as the context requires. Additionally, throughout the present application and across different embodiments, like reference numerals denote like features with similar structures and compositions, unless otherwise excepted. Source/drain region(s) may refer to a source or a drain, individually or collectively dependent upon the context.

Method 100 forms a CFET structure where a bottom contact etch stop layer (CESL) over a bottom source/drain feature is different from a top CESL over a top source/drain feature. The bottom CESL is configured to exert a compressive stress on bottom channels and the top CESL is configured to exert a tensile stress on top channels.

Referring to FIGS. 1 and 2, method 100 includes a block 102 where a fin-shaped structure 210 is formed from a superlattice 204 on a substrate 202. The substrate 202 in FIG. 2 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). In some alternative embodiments, the substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

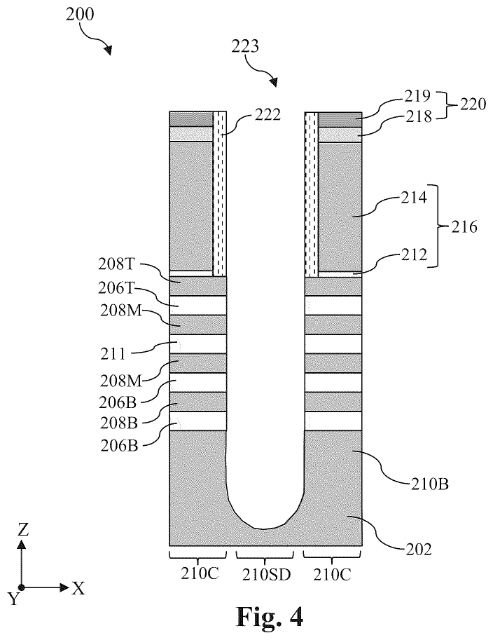

Reference is made to FIG. 2. The superlattice 204 may be deposited using epitaxial processes and includes silicon (Si) layers interleaved by silicon germanium (SiGe) layers. Example epitaxial processes may include vapor phase epitaxy (VPE), ultra-high-vacuum chemical vapor deposition (UHV-CVD), or molecular beam epitaxy (MBE). In the depicted embodiments, the silicon layers include a bottom silicon layer 208B, two middle silicon layers 208M and a top silicon layer 208T and the silicon germanium layers include two bottom silicon germanium layers 206B, a middle silicon germanium layer 206M, and a top silicon germanium layer 206T. The bottom silicon layer 208B is sandwiched vertically between the two bottom silicon germanium layers 206B. The middle silicon germanium layer 206M is sandwiched between two bottom silicon layers 208B. The top silicon germanium layer 206T is sandwiched between a middle silicon layer 208M and the top silicon layer 208T. The bottom silicon layer 208B, the two middle silicon layers 208M and the top silicon layer 208T may be collectively referred to as silicon layers 208. The two bottom silicon germanium layers 206B, the middle silicon germanium layer 206M, and the top silicon germanium layer 206T may be collectively referred to as silicon germanium layers 206. It should be understood that the number of layers in the superlattice 204 shown in FIG. 2 is not limiting and other numbers of layers are contemplated. For example, the superlattice 204 shown in FIG. 4 includes four (4) silicon layers 208 and four (4) silicon germanium layers 206. In some other examples, the superlattice 204 may include different numbers of silicon layers and/or silicon germanium layers. Additionally, the number of the silicon layers and the number of the silicon germanium layers may be the same or different.

At block 102, a fin-shaped structure 210 is formed from the superlattice 204 and a portion of the substrate 202. For patterning purposes, a hard mask layer may be deposited over the superlattice 204. The hard mask layer may be a single layer or a multilayer. In one example, the hard mask layer includes a silicon oxide layer and a silicon nitride layer over the silicon oxide layer. As shown in FIG. 2, the fin-shaped structure 210 extends vertically along the Z direction from the substrate 202 and extends lengthwise along the X direction. The fin-shaped structure 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice 204 and the substrate 202 to form the fin-shaped structure 210. The portion of the fin-shaped structure 210 formed from the substrate 202 may be referred to as a base fin 210B or base portion 210B. The etching process may include dry etching, wet etching, reactive ion etching (RIE), and/or other suitable processes.

After the fin-shaped structure 210 is formed, an isolation feature is formed around the base fin 210B or the fin-shaped structure 210 to separate the fin-shaped structure 210 from an adjacent fin-shaped structure 210. The isolation feature may also be referred to as a shallow trench isolation (STI) feature. In an example process, a dielectric material for the isolation feature is deposited over the workpiece 200, including the fin-shaped structure 210, using chemical vapor deposition (CVD), subatmospheric CVD (SACVD), flowable CVD (FCVD), spin-on coating, and/or other suitable process. Then the deposited dielectric material is planarized and recessed to form the isolation feature. The fin-shaped structure 210 rises above the isolation feature and the isolation feature surrounds the base fin 210B of the fin-shaped structure 210. The dielectric material for the isolation feature may include silicon oxide, silicon oxynitride, fluorine-doped silicate glass (FSG), a low-k dielectric, combinations thereof, and/or other suitable materials.

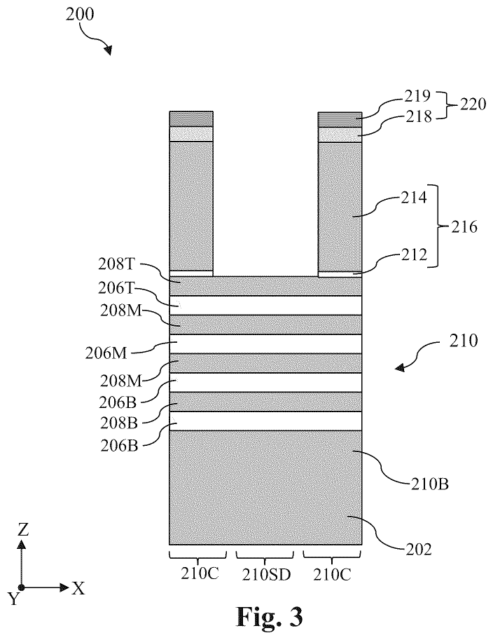

Referring to FIGS. 1 and 3, method 100 includes a block 104 where dummy gate stacks 216 are formed over channel regions 210C of the fin-shaped structure 210. At block 104, dummy gate stacks 216 are formed over channel regions 210C of the fin-shaped structures 210. To form the dummy gate stack 216, a dummy dielectric layer 212, a dummy gate electrode layer 214, and a gate-top hard mask layer 220 are deposited over the precursor structure 200. The deposition of these layers may include use of low-pressure CVD (LPCVD), CVD, plasma-enhanced CVD (PECVD), PVD, ALD, thermal oxidation, e-beam evaporation, or other suitable deposition techniques, or combinations thereof. The dummy dielectric layer 212 may include silicon oxide, the dummy gate electrode layer 214 may include polysilicon, and the gate-top hard mask layer 220 may be a multi-layer. In the depicted embodiment, the gate-top hard mask layer 220 includes a first layer 218 and a second layer 219 over the first layer 218. The first layer 218 may include silicon oxide and the second layer 219 may include silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching (e.g., RIE etching), wet etching, and/or other etching methods. Like the fin-shaped structures 210, the dummy gate stacks 216 may also be patterned using double-patterning or multiple-patterning techniques. Thereafter, using the patterned gate-top hard mask layer 220 as the etch mask, the dummy dielectric layer 212 and the dummy gate electrode layer 214 are then etched to form the dummy gate stacks 216. The dummy gate stacks 216 extend lengthwise along the Y direction to wrap over the fin-shaped structure 210 and lands on the isolation feature. The portion of the fin-shaped structure 210 underlying the dummy gate stacks 216 define the channel regions 210C. The channel regions 210C and the dummy gate stacks 216 also define source/drain regions 210SD that are not vertically overlapped by the dummy gate stacks 216. The channel region 210C is disposed between two source/drain regions 210SD along the X direction.

Referring to FIGS. 1 and 4, method 100 includes a block 106 where a source/drain region 210SD of the fin-shaped structure 210 is recessed. FIG. 4 shows a fin-shaped structures 210 extending along the X direction. Operations at block 106 may include formation of the gate spacer 222 over the sidewalls of the dummy gate stack 216 over the fin-shaped structure 210 before the source/drain regions 210SD are recessed. In some embodiments, the formation of the gate spacer 222 includes deposition of one or more dielectric layers over the precursor structure 200, including the dummy gate stacks 216. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the deposition of the one or more dielectric layers, the precursor structure 200 is etched in an anisotropic etch process to form the source/drain trenches 223. The etch process at block 104 may be a dry etch process or a suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. After the source/drain trenches 223 are formed, sidewalls of the silicon germanium layers 206 and the silicon layers 208 in the channel regions 210C are exposed in the source/drain trenches 223. In the embodiments represented in FIG. 4, bottom surfaces of the source/drain trenches 223 terminate in the substrate 202.

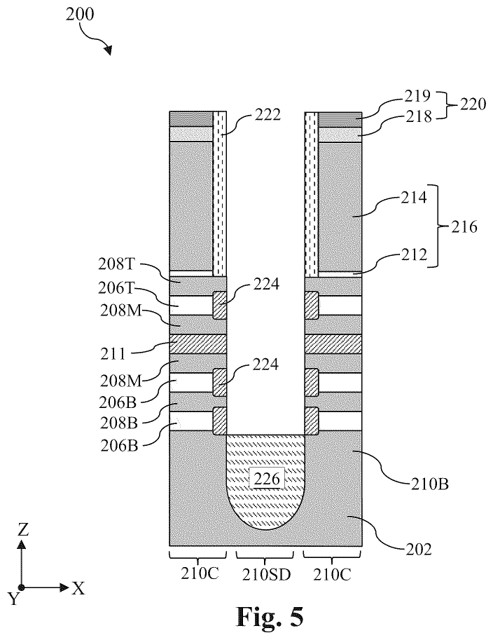

Referring to FIGS. 1 and 5, method 100 includes a block 108 where inner spacer features 224 are formed. The inner spacer features 224 and the middle dielectric layer 211 are formed after the formation of the source/drain trenches 223. To form the inner spacer features 224, the silicon germanium layers 206B and 206T exposed in the source/drain trenches 223 are selectively and partially recessed to form inner spacer recesses, while the exposed silicon layers 208B, 208M and 208T are substantially unetched. The middle silicon germanium layer 206M (shown in FIG. 4), which includes a greater germanium content than the other silicon germanium layers 206B and 206T, may be substantially removed during the formation of inner spacer recesses. After the formation of the inner spacer recesses, an inner spacer material layer is deposited over the precursor structure 200, including in the inner spacer recesses. Additionally, as shown in FIG. 5, the inner spacer material layer may also be deposited in the space left vacant by the removal of the middle silicon germanium layer 206M to form the middle dielectric layer 211. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material layer over the gate spacer 222 and sidewalls of the silicon layers 208, thereby forming the inner spacer features 224 and the middle dielectric layer 211 as shown in FIG. 5.

Referring to FIGS. 1 and 5, method 100 includes a block 110 where a base epitaxial layer 226 is formed in the source/drain trench 223. The base epitaxial layer 226 functions to reduce leakage into the substrate 202. The base epitaxial layer 226 may include undoped semiconductor material. In the depicted embodiments, the base epitaxial layer 226 includes undoped silicon (Si), undoped silicon germanium (SiGe), or undoped germanium (Ge). In these embodiments, the base epitaxial layer 226 may be deposited using vapor-phase epitaxy (VPE), ultra-high vacuum chemical vapor deposition (UHV-CVD), molecular beam epitaxy (MBE), and/or other suitable epitaxy deposition processes. To ensure that the base epitaxial layer 226 is disposed in the substrate 202, a first epitaxy blocking layer may be formed over sidewalls of the silicon layers (such as the bottom silicon layer 208B, the middle silicon layers 208M, and the top silicon layer 208T) before the deposition of the base epitaxial layer 226. The first epitaxial blocking layer may include a dielectric material, such as silicon oxide, silicon nitride, or aluminum oxide. The first epitaxy blocking layer is then selectively removed after the deposition of the base epitaxial layer 226. Alternatively, the base epitaxial layer 226 may be deposited over the source/drain trench 223 and then an etch back is performed until a top surface of the base epitaxial layer 226 is substantially level a bottom surface of the bottom silicon germanium layer 206B.

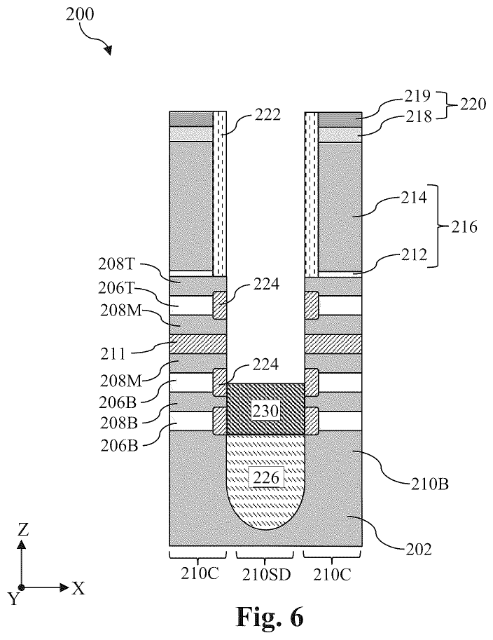

Referring to FIGS. 1 and 6, method 100 includes a block 112 where a bottom source/drain feature 230 is formed over the base epitaxial layer 226. The bottom source/drain feature 230 may be formed using an epitaxial process, such as VPE, UHV-CVD, MBE, and/or other suitable processes. The epitaxial growth process may use gaseous and/or liquid precursors, which interact with the composition of the base epitaxial layer 226 as well as the bottom silicon layers 208B. The epitaxial growth of the bottom source/drain feature 230 may take place from both the top surface of the base epitaxial layer 226 and the exposed sidewalls of the bottom silicon layer 208B. The selective epitaxial growth of the bottom source/drain feature 230 may be achieved by depositing a second epitaxy blocking layer to cover the exposed end walls of the middle silicon layers 208M and the top silicon layer 208T. The second epitaxy blocking layer may be similar to the first epitaxy blocking layer in terms of compositions and formation processes. After the deposition of the bottom source/drain feature 230, the second epitaxy blocking layer is selectively removed. In the embodiments represented in the figures, the bottom source/drain feature 230 is p-type and includes silicon germanium (SiGe) doped with a p-type dopant, such as boron (B) In these depicted embodiments, the bottom source/drain feature 230 may include boron doped silicon germanium (SiGe:B).

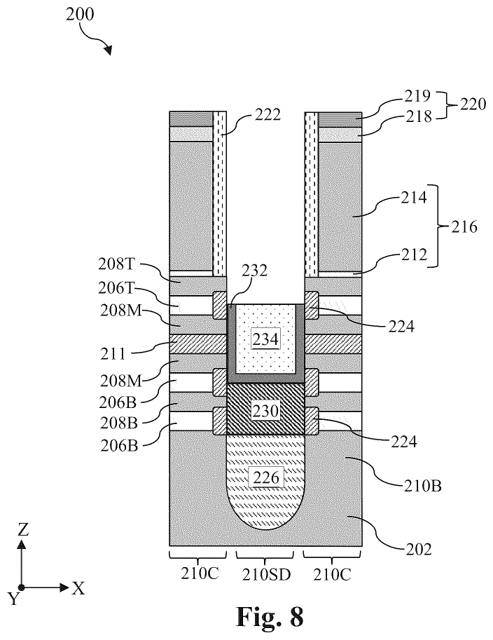

Referring to FIGS. 1, 7 and 8, method 100 includes a block 114 where a bottom contact etch stop layer (CESL) 232 and a bottom interlayer dielectric (ILD) layer 234 are formed over the bottom source/drain feature 230. According to the present disclosure, the bottom CESL 232 is configured to exert a compressive stress on bottom silicon layers 208B. The bottom CESL 232 may include silicon (Si), oxygen (O), carbon (C), or nitrogen (N). In some embodiments, the bottom CESL 232 may include between about 30% and about 70% of oxygen, between about 0% and about 15% of carbon, and between about 0% and about 30% of nitrogen. In other words, the bottom CESL 232 may include silicon oxynitride, silicon oxycarbide, or silicon oxycarbonitride, albeit with a higher oxygen content. The bottom CESL 232 may be deposited using atomic layer deposition (ALD) or chemical vapor deposition (CVD) and precursors such as silane, ammonia, oxygen, or hydrocarbons. It has been observed that a stress exerted by the bottom CESL 232 on the bottom silicon layers 208B may be between about 0.5 Gpa and about 1.5 Gpa. In some embodiments represented in FIG. 8, the bottom CESL 232 comes in contact with at least one of the inner spacer features 224, either below or above the middle dielectric layer 211.

The bottom ILD layer 234 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. and may be formed by CVD, ALD, plasma-enhanced chemical vapor deposition (PECVD) process and/or other suitable deposition or oxidation processes. In some embodiments, the bottom ILD layer 234 is deposited over the bottom CESL 232 by spin-on coating, FCVD, CVD, or other suitable deposition technique. A composition of the bottom ILD layer 234 is different from a composition of the bottom CESL 232. In some embodiments, after formation of the bottom ILD layer 234, the precursor structure 200 may be annealed to improve integrity of the bottom ILD layer 234. As shown in FIG. 8, after the deposition of the bottom CESL 232 and the bottom ILD layer 234, the bottom CESL 232 and the bottom ILD layer 234 are etched back to exposed sidewalls of the top silicon layers 208T.

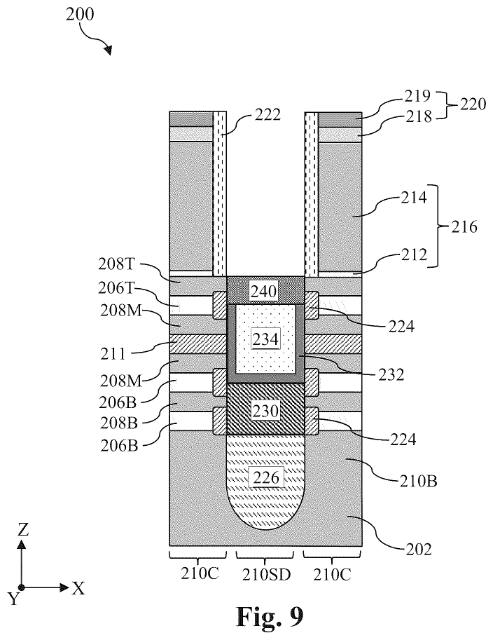

Referring to FIGS. 1 and 9, method 100 includes a block 116 where a top source/drain feature 240 is formed over the bottom CESL 232 and the bottom ILD layer 234. The top source/drain features 240 may be formed using an epitaxial process, such as VPE, UHV-CVD, MBE, and/or other suitable processes. The epitaxial growth process may use gaseous and/or liquid precursors, which interact with composition of the top silicon layer 208T. The epitaxial growth of top source/drain feature 240 may take place from the exposed sidewalls of the top silicon layer 208T. The deposited top source/drain feature 240 is in physical contact with (or adjoining) the top silicon layer 208T. In the depicted embodiments, the top source/drain feature 240 is an n-type source/drain feature and may include silicon (Si) doped with an n-type dopant, such as phosphorus (P). In these depicted embodiments, the top source/drain feature 240 may include phosphorus doped silicon (Si:P).

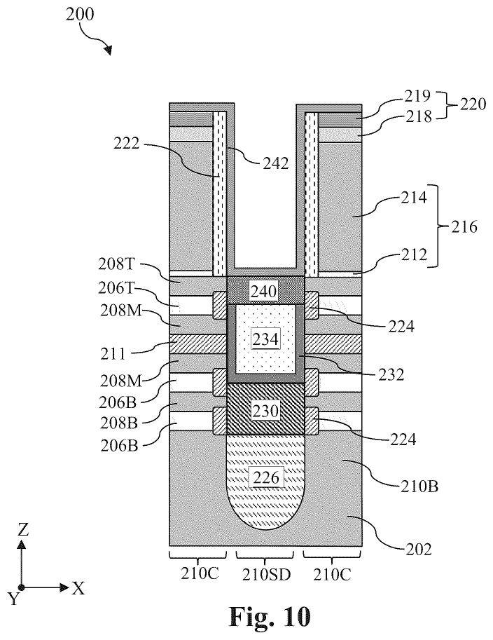

Referring to FIGS. 1, 10, 11, and 12, method 100 includes a block 118 where a top contact etch stop layer (CESL) 242 and a top interlayer dielectric (ILD) layer 244 are formed over the top source/drain feature 240. Reference is first made to FIG. 10. According to the present disclosure, the top CESL 242 is configured to exert a tensile stress on top silicon layers 208T. The top CESL 242 may include silicon (Si), oxygen (O), carbon (C), or nitrogen (N). In some embodiments, the top CESL 242 may include between about 0% and about 40% of oxygen, between about 0% and about 15% of carbon, and between about 15% and about 60% of nitrogen. In other words, the top CESL 242 may include silicon nitride or silicon oxycarbonitride, albeit with a higher nitrogen content. The top CESL 242 may be deposited using ALD or CVD CVD) and precursors such as silane, ammonia, oxygen, or hydrocarbons. It has been observed that a stress exerted by the top CESL 242 on the top silicon layers 208T may be between about 0.5 Gpa and about 1.5 Gpa. As compared to the bottom CESL 232, the top CESL 242 has a greater nitrogen content and a smaller oxygen content.

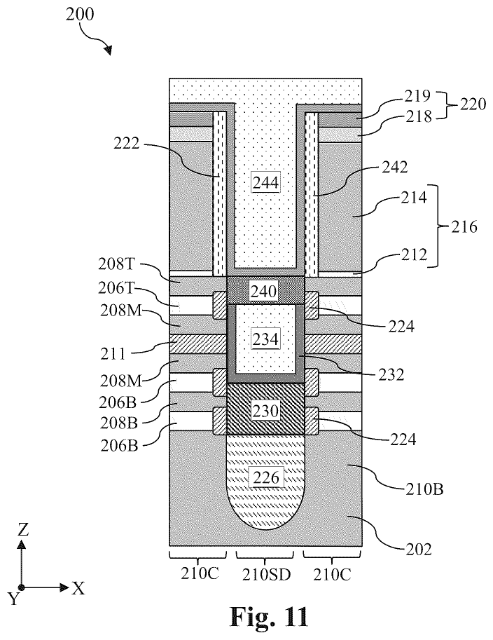

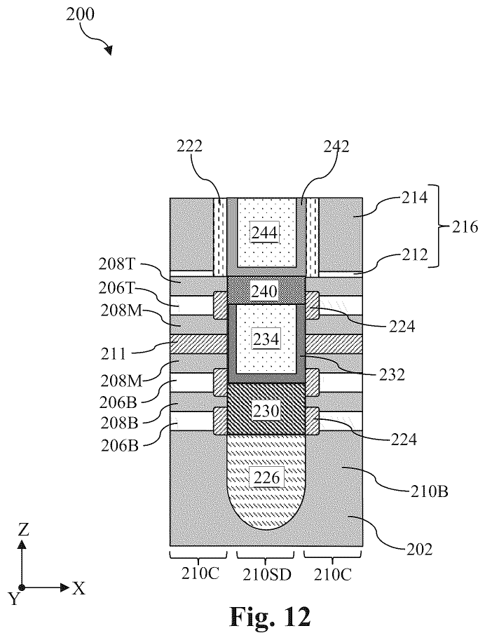

Referring to FIG. 11, the top ILD layer 244 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. and may be formed by CVD, ALD, plasma-enhanced chemical vapor deposition (PECVD) process and/or other suitable deposition or oxidation processes. In some embodiments, the top ILD layer 244 is deposited over the top CESL 242 by spin-on coating, FCVD, CVD, or other suitable deposition technique. A composition of the top ILD layer 244 is different from a composition of the top CESL 242. In some embodiments, after formation of the top ILD layer 244, the precursor structure 200 may be annealed to improve integrity of the top ILD layer 244. As shown in FIG. 12, after the deposition of the top CESL 242 and the top ILD layer 244, a planarization process, such a chemical mechanical polishing (CMP) process may be performed to remove excess materials and to expose top surfaces of the dummy gate stacks 216. In FIG. 12, the top ILD layer 244 is spaced apart from the gate spacer 222 by the top CESL 242.

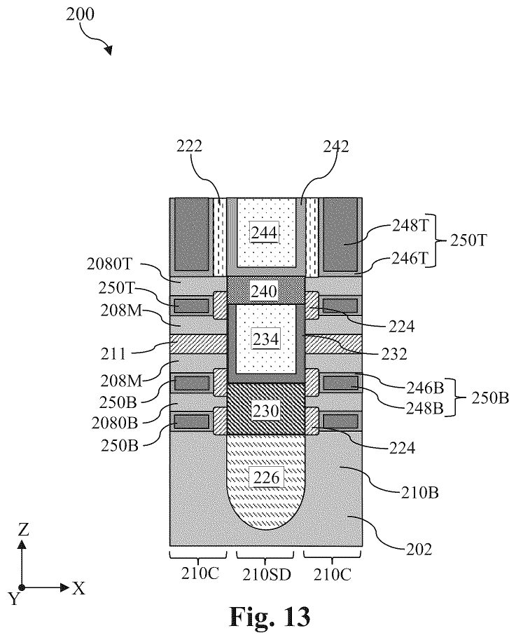

Referring to FIGS. 1 and 13, method 100 includes a block 120 where the dummy gate stack 216 is replaced with a first gate structure 250B and a second gate structure 250T. The removal of the dummy gate stacks 216 may include one or more etching processes that are selective to the material in the dummy gate stacks 216. For example, the removal of the dummy gate stacks 216 may be performed using as a selective wet etch, a selective dry etch, or a combination thereof. After the removal of the dummy gate stacks 216, sidewalls of the silicon layers 208 (including the bottom silicon layer 208B, the middle silicon layers 208M, and the top silicon layer 208T) and the silicon germanium layers 206 (including the bottom silicon germanium layers 206B and the top silicon germanium layer 206T) are exposed. Thereafter, the silicon germanium layers 206 (including the bottom silicon germanium layers 206B and the top silicon germanium layer 206T) are selectively removed to release the silicon layers (including the bottom silicon layer 208B, the middle silicon layers 208M, and the top silicon layer 208T) as a top channel member 2080T and a bottom channel member 2080B. Because the dimensions of the top channel members 2080T and bottom channel members 2080B are nanoscale, they may also be referred to as nanostructures. The selective removal of the silicon germanium layers may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

With the bottom channel members 2080B and top channel members 2080T released, a bottom gate structure 250B is deposited to wrap around each of the bottom channel members 2080B and a top gate structure 250T is deposited to wrap around each of the top channel members 2080T. The bottom gate structure 250B turns on the bottom channel members 2080B and forms a bottom multi-gate transistor. The top gate structure 250T turns on the top channel members 2080T to form a top multi-gate transistor. In the embodiments represented in FIG. 13, the bottom multi-gate transistor is a p-type device and the top multi-gate transistor is an n-type device. The bottom gate structure 250B includes a bottom gate dielectric layer 246B and a bottom gate electrode 248B. The top gate structure 250T includes a top gate dielectric layer 246T and a top gate electrode 248T. While not explicitly shown in the figures, each of the bottom gate structure 250B and the top gate structure 250T further includes an interfacial layer to interface the bottom channel members 2080B or top channel members 2080T. The interfacial layer may include silicon oxide and may be formed using a thermal oxidation process or a pre-clean process. An example pre-clean process may include use of RCA SC-1 (ammonia, hydrogen peroxide and water) and/or RCA SC-2 (hydrochloric acid, hydrogen peroxide and water). The bottom gate electrode 248B includes at least one p-type work function layer. The top gate electrode 248T includes at least one n-type work function layer. The bottom gate dielectric layer 246B and the top gate dielectric layer 246T are then deposited over the interfacial layer using ALD, CVD, and/or other suitable methods. The bottom gate dielectric layer 246B and the top gate dielectric layer 246T are formed of high-K dielectric materials. As used and described herein, high-k dielectric materials include dielectric materials having a high dielectric constant, for example, greater than that of thermal silicon oxide (˜3.9). The bottom gate dielectric layer 246B and the top gate dielectric layer 246T may include hafnium oxide. Alternatively, the bottom gate dielectric layer 246B and the top gate dielectric layer 246T may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. In fact, a dielectric constant of the bottom gate dielectric layer 246B and the top gate dielectric layer 246T is greater than a dielectric constant of the bottom CESL 232, the bottom ILD layer 234, the top CESL 242, the top ILD layer 244, the gate spacer 222, or the inner spacer features 224. The bottom gate dielectric layer 246B and the top gate dielectric layer 246T is thinner than the gate spacer 222 as it does not need to withstand multiple etch processes.

After the deposition of the bottom gate dielectric layer 246B and the top gate dielectric layer 246T, the bottom gate electrode 248B may be deposited to form the bottom gate structure 250B and the top gate electrode 248T may be deposited to form the top gate structure 250T. Each of the bottom gate structure 250B and the top gate structure 250T may also include a liner layer, a wetting layer, an adhesion layer, a metal alloy or a metal silicide. By way of example, the at least one p-type work function layer in the bottom gate structure 250B may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The at least one n-type work function layer in the top gate structure 250T may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. In some instances, the top gate electrode 248T may also include a metal fill to reduce contact resistance. In some instance, the metal fill includes tungsten (W). Because both n-type work function material and the p-type work function material are likely to include titanium, the bottom gate structure 250B and the top gate structure 250T may be said to include a titanium-based material. As shown in FIG. 13, the bottom gate structure 250B wraps around each of the bottom channel members 2080B and the top gate structure 250T wraps around each of the top channel members 2080T. In the embodiments represented in FIG. 13, the two middle silicon layers 208M are not released as the bottom channel members 2080B or the top channel members 2080T. They remain in contact with the middle dielectric layer 211. Further, the two middle silicon layers 208M are end-capped by the top CESL 242 along the X direction.

Method 300 in FIG. 14 forms a CFET semiconductor structure where a bottom CESL extends into a bottom recess of a bottom source/drain feature and a top CESL extends into a top recess of a top source/drain feature. The bottom recess and the top recess allow greater engagement of the bottom CESL and the top CESL to exert stress on the bottom channel members and the top channel members.

Referring to FIGS. 14 and 2, method 300 includes a block 302 where a fin-shaped structure 210 is formed from a superlattice 204 on a substrate 202. Operations at block 302 are substantially similar to those at block 102 described above. Detailed description of the operations at block 302 are omitted for brevity.

Referring to FIGS. 14 and 3, method 300 includes a block 304 where dummy gate stacks 216 are formed over channel regions 210C of the fin-shaped structure 210. Operations at block 304 are substantially similar to those at block 104 described above. Detailed description of the operations at block 304 are omitted for brevity.

Referring to FIGS. 14 and 4, method 300 includes a block 306 where a source/drain region 210SD of the fin-shaped structure 210 is recessed. Operations at block 306 are substantially similar to those at block 106 described above. Detailed description of the operations at block 306 are omitted for brevity.

Referring to FIGS. 14 and 5, method 300 includes a block 308 where inner spacer features 224 are formed. Operations at block 308 are substantially similar to those at block 108 described above. Detailed description of the operations at block 308 are omitted for brevity.

Referring to FIGS. 14 and 15, method 300 includes a block 310 where a base epitaxial layer 226 is formed in the source/drain trench 223. Operations at block 310 are substantially similar to those at block 110 described above. Detailed description of the operations at block 310 are omitted for brevity.

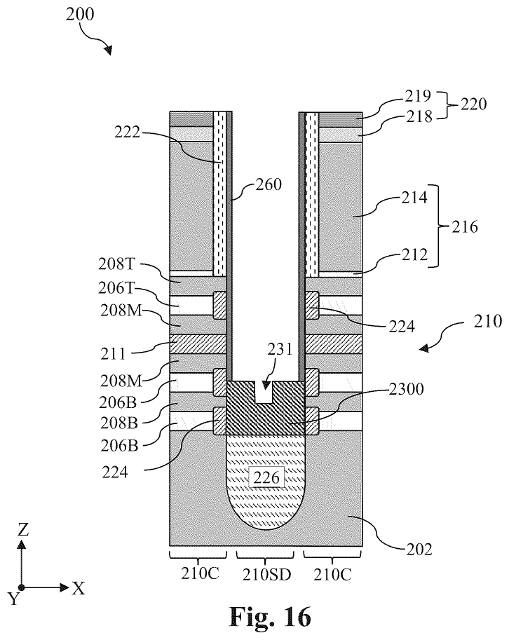

Referring to FIGS. 14, 16 and 17, method 300 includes a block 312 where a bottom source/drain feature 2300 is formed over the base epitaxial layer 226. The bottom source/drain feature 2300 may be formed using an epitaxial process, such as VPE, UHV-CVD, MBE, and/or other suitable processes. The epitaxial growth process may use gaseous and/or liquid precursors, which interact with the composition of the base epitaxial layer 226 as well as the bottom silicon layers 208B. The epitaxial growth of the bottom source/drain feature 2300 may take place from both the top surface of the base epitaxial layer 226 and the exposed sidewalls of the bottom silicon layer 208B. The selective epitaxial growth of the bottom source/drain feature 2300 may be achieved by depositing a third epitaxy blocking layer 260 to cover the exposed end walls of the middle silicon layers 208M and the top silicon layer 208T. The third epitaxy blocking layer 260 may be similar to the first epitaxy blocking layer in terms of compositions and formation processes. In some implementations, the third epitaxy blocking layer 260 may include silicon nitride or aluminum oxide. In some embodiments represented in FIG. 16, the epitaxial deposition of the bottom source/drain feature 2300 may include faceted growth such that a bottom recess 231 is formed in the bottom source/drain feature 2300. After the deposition of the bottom source/drain feature 2300, the second epitaxy blocking layer is selectively removed. In the embodiments represented in the figures, the bottom source/drain feature 2300 is p-type and includes silicon germanium (SiGe) doped with a p-type dopant, such as boron (B) In these depicted embodiments, the bottom source/drain feature 2300 may include boron doped silicon germanium (SiGe:B).

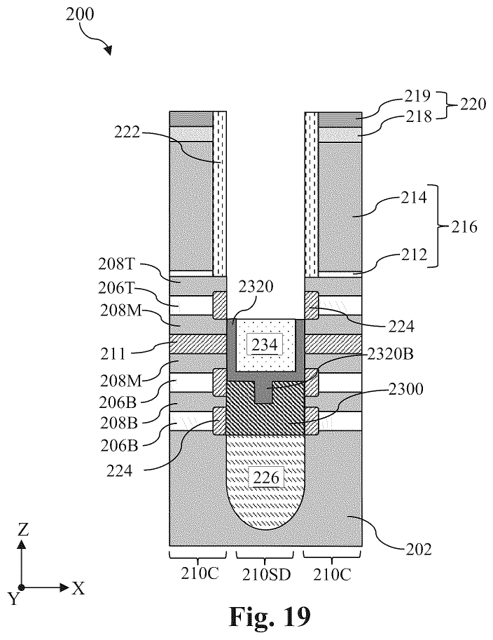

Referring to FIGS. 14, 18 and 19, method 300 includes a block 314 where a bottom contact etch stop layer (CESL) 2320 and a bottom interlayer dielectric (ILD) layer 234 are formed over the bottom source/drain feature 2300. A composition of the bottom CESL 2320 may be similar to that of the bottom CESL 232 in FIG. 8. The bottom CESL 2320 includes a bottom plug portion 2320B disposed in the bottom recess 231. That is, the bottom plug portion 2320B at least partially extends into the bottom source/drain feature 2300. In extreme cases where the bottom recess 231 extends though the bottom source/drain feature 2300 to reach the base epitaxial layer 226, the bottom plug portion 2320B may also extend through the bottom source/drain feature 2300. The bottom plug portion 2320B is continuous with the rest of the bottom CESL 2320. The bottom ILD 234 is then deposited over the bottom CESL 2320. In some embodiments represented in FIG. 19, the bottom CESL 2320 comes in contact with at least one of the inner spacer features 224, either below or above the middle dielectric layer 211. In some implementations, the bottom plug portion 2320B extends to a level such that a portion thereof is disposed between two bottom silicon layers along the channel-length direction (i.e., the X direction).

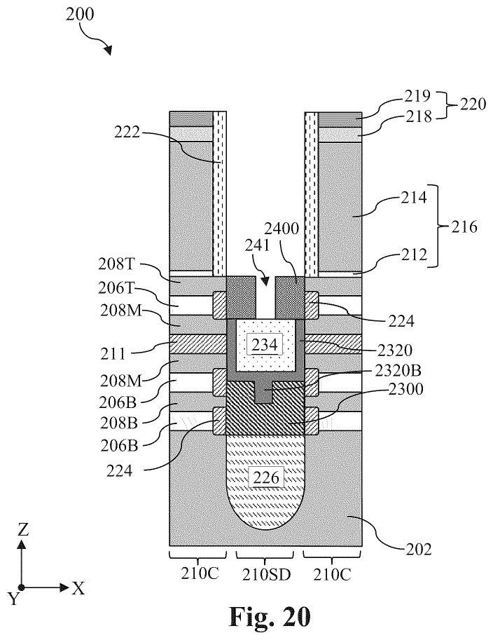

Referring to FIGS. 14 and 20, method 300 includes a block 316 where a top source/drain feature 2400 is formed over the bottom CESL 232 and the bottom ILD layer 234. The top source/drain features 240 may be formed using an epitaxial process, such as VPE, UHV-CVD, MBE, and/or other suitable processes. The epitaxial growth process may use gaseous and/or liquid precursors, which interact with composition of the top silicon layer 208T. The epitaxial growth of top source/drain feature 2400 may take place from the exposed sidewalls of the top silicon layer 208T. The deposited top source/drain feature 2400 is in physical contact with (or adjoining) the top silicon layer 208T. The selective epitaxial growth of the top source/drain feature 2400 may be achieved without needing to deposit any epitaxy blocking layer because end walls of the top silicon layer 208T are the only exposed semiconductor surfaces. In some embodiments represented in FIG. 20, the epitaxial deposition of the top source/drain feature 2400 may include faceted growth such that a top recess 241 is formed in the top source/drain feature 2400. Because top source/drain feature 2400 is not substantially deposited on the bottom CESL 2320 and the bottom ILD layer 234, the top recess 241 may extend through the top source/drain feature 2400 to expose the bottom ILD layer 234. As a comparison, the bottom recess 231 partially extends into the bottom source/drain feature 2300 and terminates in the bottom source/drain feature 2300. In the depicted embodiments, the top source/drain feature 2400 is an n-type source/drain feature and may include silicon (Si) doped with an n-type dopant, such as phosphorus (P). In these depicted embodiments, the top source/drain feature 2400 may include phosphorus doped silicon (Si:P).

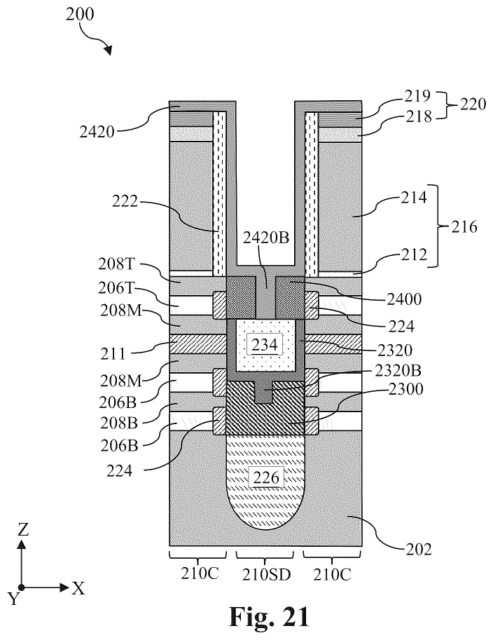

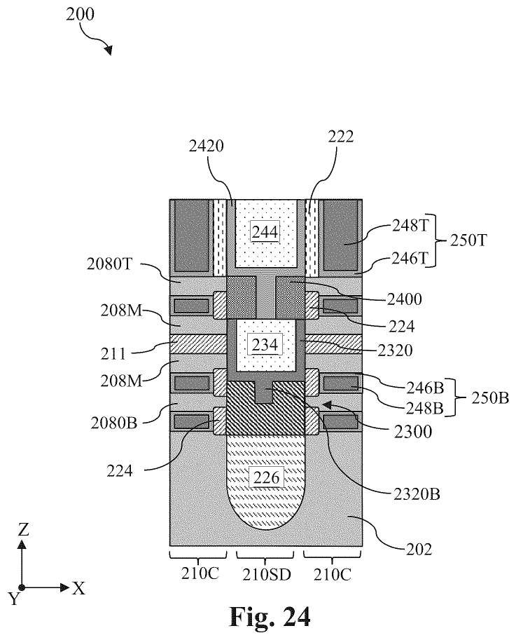

Referring to FIGS. 14, 21, 22, and 23, method 300 includes a block 318 where a top contact etch stop layer (CESL) 2420 and a top interlayer dielectric (ILD) layer 244 are formed over the top source/drain feature 2400. A composition of the top CESL 2420 may be similar to that of the top CESL 242 in FIG. 21. The top CESL 2420 includes a top plug portion 2420B disposed in the top recess 241. That is, the top plug portion 2420B at least partially extends into the top source/drain feature 2400. In the depicted embodiments where the top recess 241 extending through the top source/drain feature 2400, the top plug portion 2420B extends through the top source/drain feature 2400. The top plug portion 2420B is continuous with the rest of the top CESL 2420. The top ILD layer 244 is then deposited over the top CESL 2420. As shown in FIG. 24, the top ILD layer 244 is spaced apart from the gate spacer 222 by the top CESL 2420.

Referring to FIGS. 14 and 24, method 300 includes a block 320 where the dummy gate stack 216 is replaced with a first gate structure 250B and a second gate structure 250T. Operations at block 320 are substantially similar to those at block 120 described above. Detailed description of the operations at block 320 are omitted for brevity. Referring to FIG. 24, the bottom gate structure 250B wraps around each of the bottom channel members 2080B and the top gate structure 250T wraps around each of the top channel members 2080T. It should be noted that method 300 may optionally end at block 320. That is, the bottom CESL 2320 and the top CESL 2420 are left in place to exert compressive stress to the bottom channel members 2080B or tensile stress to the top channel members 2080T, respectively.

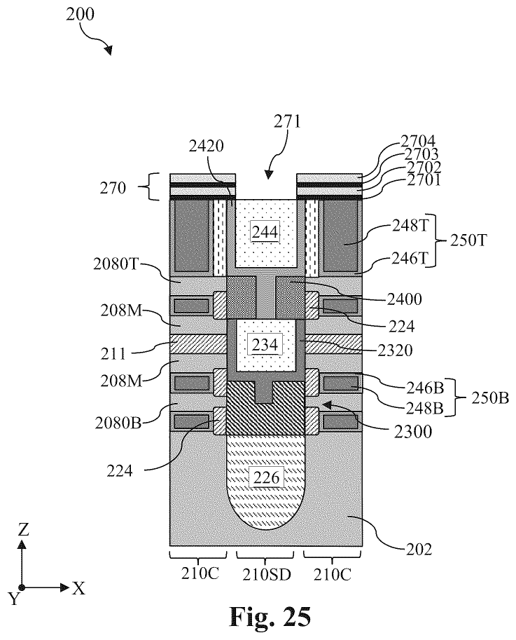

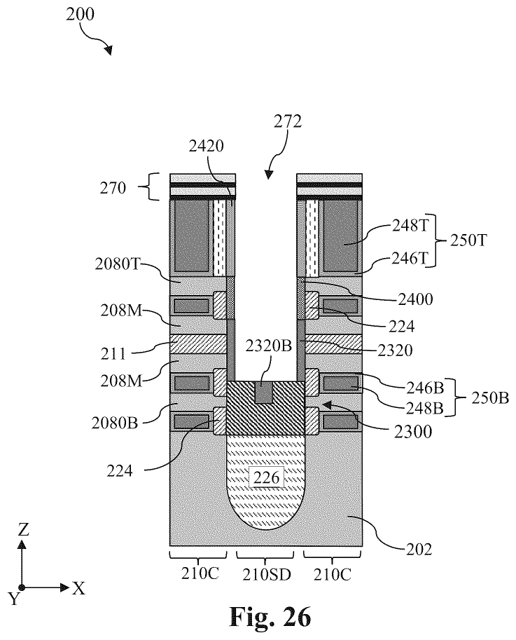

Referring to FIGS. 14, 25, and 26, method 300 includes a block 322 where a contact opening 272 is formed to expose the bottom source/drain feature 2300. In an example process, a patterned hard mask 270 is formed over the precursor structure 200. The patterned hard mask 270 includes an opening 271 to expose the top ILD layer 244. Considering the contact opening 272 has a high aspect ratio, the patterned hard mask 270 may include multiple layers. In the embodiments represented in FIG. 25, the patterned hard mask 270 includes a first silicon nitride layer 2701, a first silicon oxide layer 2702 over the first silicon nitride layer 2701, a second silicon nitride layer 2703 over the first silicon oxide layer 2702, and a second silicon oxide layer 2704 over the second silicon nitride layer 2703. Using the patterned hard mask 270 as an etch mask, one or more dry etch process is performed to extend through the top ILD layer 244, the top CESL 2420, the bottom ILD layer 234, and the bottom CESL 2320 to form the contact opening 272. The bottom source/drain feature 2300 is exposed in the contact opening 272. It is noted that, as shown in FIG. 26, a bottom plug portion 2320B of the bottom CESL 2320 may remain in the bottom recess 231 (shown in FIG. 16). In some embodiments represented in FIG. 26, formation of the contact opening 272 does not completely remove the top source/drain feature 2400, portions of the top source/drain feature 2400 cover end walls of the top channel members 2080T. Additionally, the contact opening 272 remains spaced apart from the two middle silicon layers 208M and the middle dielectric layer 211 by a residual portion of the bottom CESL 2320. The bottom plug portion 2320B is also exposed in the contact opening 272.

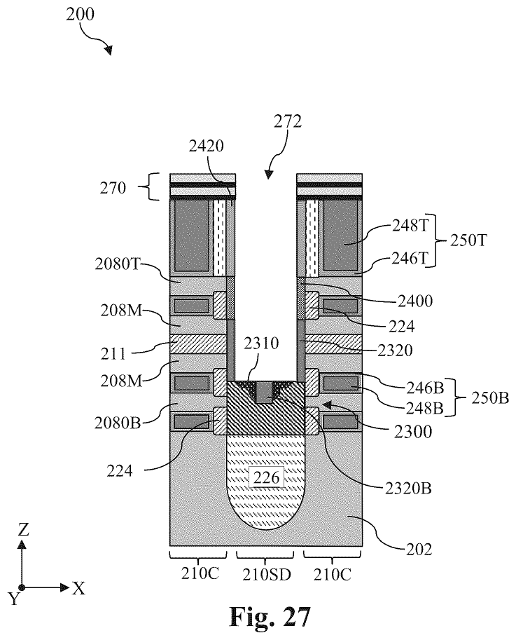

Referring to FIGS. 14 and 27, method 300 includes a block 324 where a bottom silicide feature 2310 is formed. In some embodiments, a precursor metal layer is deposited over the contact opening 272. An anneal process is then performed to cause the precursor metal layer to react with the exposed surfaces of the bottom source/drain feature 2300. The silicidation reaction forms a bottom silicide feature 2310. The bottom silicide feature 2310 is formed at corners of the bottom source/drain feature 2300 around the bottom plug portion 2320B. After the formation of the bottom silicide feature 2310, the excess precursor metal layer, especially the portion not deposited on a semiconductor surface, is selectively removed. In some embodiments, the precursor meal layer includes titanium and the bottom silicide feature 2310 includes titanium silicide. In some embodiments, when viewed along the Y direction, the bottom silicide feature 2310 may have an L-shape. The electrical conductivity of the bottom silicide feature 2310 falls between the electrical conductivity of the contact feature 280 and the electrical conductivity of the bottom source/drain feature 2300. An electrically conductivity of the bottom silicide feature 2310 is greater than that of the bottom source/drain feature 2300 but is smaller than that of the contact feature 280.

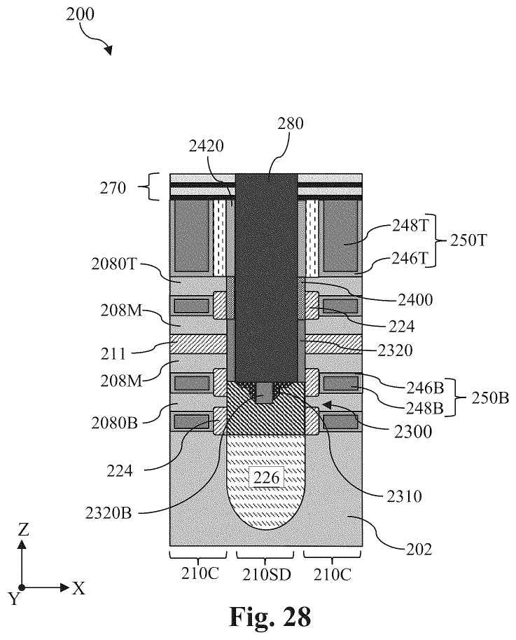

Referring to FIGS. 14 and 28, method 300 includes a block 326 where a contact feature 280 is formed in the contact opening 272. At block 326, a metal layer is deposited over the contact opening 272. A planarization process is then performed to remove the excess metal layer and form a contact feature 280. In some embodiments, the contact feature 280 may include tungsten (W), ruthenium (Ru), or molybdenum (Mo). In one embodiment, the contact feature 280 is formed of tungsten (W). In some embodiments represented in FIG. 28, the planarization process at block 326 does not remove the patterned hard mask 270. That is, top surfaces of the patterned hard mask 270 and the contact feature 280 are coplanar. Sidewalls of the contact feature 280 are in contact with the remaining portion of the bottom CESL 2320, the sidewall portions of the top source/drain feature 2400, the remaining portion of the top CESL 2420, and layers in the patterned hard mask 270.

In one exemplary aspect, the present disclosure is directed to a semiconductor device. The semiconductor device includes a substrate, an undoped semiconductor feature in the substrate, a first bottom nanostructure and a second bottom nanostructure over the substrate, a bottom epitaxial feature over the undoped semiconductor feature and extending between the first bottom nanostructure and the second bottom nanostructure, a first isolation layer over the first bottom nanostructure, a second isolation layer over the second bottom nanostructure, a bottom contact etch stop layer (CESL) over the bottom epitaxial feature, a bottom interlayer dielectric (ILD) layer the bottom CESL, a first top nanostructure over the first isolation layer, a second top nanostructure over the second isolation layer, a top epitaxial feature over the bottom CESL and bottom ILD layer and extending between the first top nanostructure and the second top nanostructure, a top CESL over the top epitaxial feature, and a top ILD layer over the top CESL. A composition of the bottom CESL is different from a composition of the top CESL.

In some embodiments, the bottom epitaxial feature includes silicon germanium (SiGe) and a p-type dopant. In some embodiments, the top epitaxial feature includes silicon (Si) and an n-type dopant. In some implementations, an oxygen content in the bottom CESL is greater than an oxygen content in the top CESL. In some embodiments, a nitrogen content in the top CESL is greater than a nitrogen content in the bottom CESL. In some instances, a portion of the bottom CESL extends into the bottom epitaxial feature and a portion of the top CESL extends through the top epitaxial feature. In some embodiments, the undoped semiconductor feature includes silicon or silicon germanium. In some instances, the semiconductor structure further includes a first bottom gate structure wrapping around the first bottom nanostructure, a second bottom gate structure wrapping around the second bottom nanostructure, a first top gate structure wrapping around the first top nanostructure, and a second top gate structure wrapping around the second top nanostructure.

In another exemplary aspect, the present disclosure is directed to a semiconductor structure. The semiconductor structure includes a substrate, an undoped semiconductor feature in the substrate, a first bottom nanostructure and a second bottom nanostructure over the substrate, a bottom epitaxial feature over the undoped semiconductor feature and sandwiched between the first bottom nanostructure and the second bottom nanostructure, a first isolation layer over the first bottom nanostructure, a second isolation layer over the second bottom nanostructure, a bottom contact etch stop layer (CESL) including a bottom portion extending into the bottom epitaxial feature, a first sidewall portion covering a sidewall of the first isolation layer, and a second sidewall portion covering a sidewall of the second isolation layer, a first top nanostructure over the first isolation layer, a second top nanostructure over the second isolation layer, and a contact feature over the bottom portion and the bottom epitaxial feature. The contact feature interfaces a top surface of the bottom portion of the bottom CESL, the contact feature interfaces the bottom epitaxial feature by way of a silicide feature, and the contact feature is sandwiched between and interfaces the first sidewall portion and the second sidewall portion.

In some embodiments, the contact feature is spaced apart from sidewalls of the first top nanostructure and the second top nanostructure by a top epitaxial feature. In some implementations, the bottom epitaxial feature includes silicon germanium and a p-type dopant and the top epitaxial feature includes silicon and an n-type dopant. In some instances, the semiconductor structure further includes a top CESL over the top epitaxial feature. In some embodiments, a composition of the bottom CESL is different from a composition of the top CESL. In some embodiments, the first bottom nanostructure and the second bottom nanostructure are aligned along a direction. In some embodiments, the bottom portion of the bottom CESL extends between the first bottom nanostructure and the second bottom nanostructure along the direction.

In yet another exemplary aspect, the present disclosure is directed to a method. The method includes forming a superlattice structure over a substrate, patterning the superlattice structure and a portion of the substrate to form a fin-shaped structure, forming a first dummy gate stack and a second dummy gate stack over a first channel region and a second channel region of the fin-shaped structure, recessing a source/drain region of the fin-shaped structure to form a source/drain trench, the source/drain region being between the first channel region and the second channel region, depositing an undoped semiconductor feature in the source/drain trench, depositing a bottom source/drain feature over the undoped semiconductor feature, the bottom source/drain feature including a first middle recess, depositing a bottom contact etch stop layer (CESL) over the first middle recess, depositing a bottom interlayer dielectric (ILD) layer over the bottom CESL, etching back the bottom CESL and the bottom ILD layer, after the etching back, depositing a top source/drain feature over the bottom CESL and the bottom ILD layer, the top source/drain feature including a second middle recess, and depositing a top CESL over the second middle recess.

In some embodiments, the bottom CESL extends into the first middle recess and the top CESL extends into the second middle recess. In some implementations, a composition of the bottom CESL is different from a composition of the top CESL. In some embodiments, the bottom source/drain feature includes silicon germanium and a p-type dopant, and the top source/drain feature includes silicon and an n-type dopant. In some implementations, a nitrogen content in the bottom CESL is greater than a nitrogen content in the top CESL.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
an undoped semiconductor feature in the substrate;
a first bottom nanostructure and a second bottom nanostructure over the substrate;
a bottom epitaxial feature over the undoped semiconductor feature and extending between the first bottom nanostructure and the second bottom nanostructure;
a first isolation layer over the first bottom nanostructure;
a second isolation layer over the second bottom nanostructure;
a bottom contact etch stop layer (CESL) over the bottom epitaxial feature;
a bottom interlayer dielectric (ILD) layer the bottom CESL;
a first top nanostructure over the first isolation layer;
a second top nanostructure over the second isolation layer;
a top epitaxial feature over the bottom CESL and bottom ILD layer and extending between the first top nanostructure and the second top nanostructure;
a top CESL over the top epitaxial feature; and
a top ILD layer over the top CESL,
wherein a composition of the bottom CESL is different from a composition of the top CESL.

2. The semiconductor structure of claim 1, wherein the bottom epitaxial feature comprises silicon germanium (SiGe) and a p-type dopant.

3. The semiconductor structure of claim 1, wherein the top epitaxial feature comprises silicon (Si) and an n-type dopant.

4. The semiconductor structure of claim 1, wherein an oxygen content in the bottom CESL is greater than an oxygen content in the top CESL.

5. The semiconductor structure of claim 1, wherein a nitrogen content in the top CESL is greater than a nitrogen content in the bottom CESL.

6. The semiconductor structure of claim 1,
wherein a portion of the bottom CESL extends into the bottom epitaxial feature,
wherein a portion of the top CESL extends through the top epitaxial feature.

7. The semiconductor structure of claim 1, wherein the undoped semiconductor feature comprises silicon or silicon germanium.

8. The semiconductor structure of claim 1, further comprising:
a first bottom gate structure wrapping around the first bottom nanostructure;
a second bottom gate structure wrapping around the second bottom nanostructure;
a first top gate structure wrapping around the first top nanostructure; and
a second top gate structure wrapping around the second top nanostructure.

9. A semiconductor structure, comprising:
a substrate;
a first bottom nanostructure and a second bottom nanostructure over the substrate;
a bottom epitaxial feature over the substrate and extending between the first bottom nanostructure and the second bottom nanostructure;
a first isolation layer over the first bottom nanostructure;
a second isolation layer over the second bottom nanostructure;
a bottom contact etch stop layer (CESL) over the bottom epitaxial feature;
a bottom interlayer dielectric (ILD) layer the bottom CESL;
a first top nanostructure over the first isolation layer;
a second top nanostructure over the second isolation layer;
a top epitaxial feature over the bottom CESL and bottom ILD layer and interfacing the first top nanostructure and the second top nanostructure;
a top CESL over the top epitaxial feature; and
a top ILD layer over the top CESL,
wherein the bottom CESL extends into the bottom epitaxial feature,
wherein the top CESL extends into the top epitaxial feature.

10. The semiconductor structure of claim 9, wherein a composition of the bottom CESL is different from a composition of the top CESL.

11. The semiconductor structure of claim 9, further comprising:
an undoped semiconductor feature below the bottom epitaxial feature,
wherein the undoped semiconductor feature extends into the substrate.

12. The semiconductor structure of claim 9, further comprising:
a bottom gate structure wrapping around the first bottom nanostructure,
wherein the bottom gate structure is spaced apart from the bottom epitaxial feature by a plurality of inner spacer features,
wherein at least one of the plurality of inner spacer features interfaces the bottom CESL.

13. The semiconductor structure of claim 9,
wherein the bottom epitaxial feature comprises silicon germanium and a p-type dopant,
wherein the top epitaxial feature comprises silicon and an n-type dopant.

14. The semiconductor structure of claim 9,
wherein the bottom epitaxial feature is disposed between the first bottom nanostructure and the second bottom nanostructure along a direction,
wherein a portion of the bottom CESL extends between the first bottom nanostructure and the second bottom nanostructure along the direction.

15. The semiconductor structure of claim 9, wherein an oxygen content in the bottom CESL is greater than an oxygen content in the top CESL.

16. A method, comprising:
forming a superlattice structure over a substrate;
patterning the superlattice structure and a portion of the substrate to form a fin-shaped structure;
forming a first dummy gate stack and a second dummy gate stack over a first channel region and a second channel region of the fin-shaped structure;
recessing a source/drain region of the fin-shaped structure to form a source/drain trench, the source/drain region being between the first channel region and the second channel region;
depositing an undoped semiconductor feature in the source/drain trench;
depositing a bottom source/drain feature over the undoped semiconductor feature, the bottom source/drain feature comprising a first middle recess;
depositing a bottom contact etch stop layer (CESL) over the first middle recess;
depositing a bottom interlayer dielectric (ILD) layer over the bottom CESL;
etching back the bottom CESL and the bottom ILD layer;
after the etching back, depositing a top source/drain feature over the bottom CESL and the bottom ILD layer, the top source/drain feature comprising a second middle recess; and
depositing a top CESL over the second middle recess.

17. The method of claim 16,
wherein the bottom CESL extends into the first middle recess,
wherein the top CESL extends into the second middle recess.

18. The method of claim 16, wherein a composition of the bottom CESL is different from a composition of the top CESL.

19. The method of claim 16,
wherein the bottom source/drain feature comprises silicon germanium and a p-type dopant,
wherein the top source/drain feature includes silicon and an n-type dopant.

20. The method of claim 16, wherein a nitrogen content in the bottom CESL is greater than a nitrogen content in the top CESL.
